(19) United States
(12) Patent Application Publication
(10) Pub. No.: US 2004/0008483 A1
(43) Pub. Date: Jan. 15, 2004

(54) Water cooling type cooling system for electronic device

(76) Inventor: Kioan Cheon, Federal Way, WA (US)

Correspondence Address: Del Barnard, Barnard & Pauly, P.S., P.O. Box 58888, Seattle, WA, 98138, US

(21) Appl. No.: 10/241,126

(22) Filed: Sep. 11, 2002

(30) Foreign Application Priority Data
Jul. 13, 2002 (KR) 2002-0040969

(51) Int. Cl. G06F 1/20; H05K 7/20

(52) U.S. Cl. 361/687; 361/699

(57) ABSTRACT

Provided is a water cooling type cooling system for an electronic device having a plurality of coolant circulation units and coolant supply units separable from each other to be interconnected in series or parallel. The water cooling type cooling system includes a coolant circulation unit including heat exchangers contacting heat sources inside the electronic device and internal circulation lines disposed inside the electronic device for circulating a coolant in the heat exchangers, a coolant supply unit including external circulation lines connected to the internal circulation lines of the coolant circulation unit and extending outside the electronic device so as to circulate the coolant outside the electronic device, heat-dissipating devices connected to the external circulation lines for emitting heat of the coolant into the air, circulation pumps connected to the external circulation lines for forming hydraulic pressure of the coolant, a coolant tank in which the coolant is stored, and a casing for protecting the heat-dissipating devices, the circulation pumps and the coolant tank, and a controller for controlling the circulation pumps by applying control signals to the circulation pumps. Therefore, components inside the electronic device are simplified, thereby facilitating assembling and maintenance works and reducing the internal temperature of the electronic device. Also, noise and vibration of the electronic device can be reduced. Further, since a plurality of small-sized electronic components are interconnected in series or parallel, a detachable, rack mount type, large-sized electronic device can be operated in a water cooling type.

### TECHNICAL FIELD

The present invention relates to a water cooling type cooling system for an electronic device, and more particularly, to a water cooling type cooling system for an electronic device having a plurality of coolant circulation units and coolant supply units separable from each other and configured such that the plurality of coolant circulation units and coolant supply units are interconnected in series or parallel.

### BACKGROUND OF THE INVENTION

In general, since a conventional water cooling type cooling system for an electronic device includes a heat-dissipating device, a circulation pump and a coolant tank inside the electronic device, the electronic device is very complex and too narrow to perform assembling and maintenance works. Also, since the electronic device is densely congested with various components, the internal temperature may excessively rise.

In particular, since it is impossible to reconstruct a conventional air cooling type electronic device into a water cooling type one, such a conventional water cooling type cooling system is difficult to be applied to the conventional air cooling type electronic device, resulting in poor marketability.

In other words, in manufacturing a water cooling type electronic device adapted to high-performance semiconductor chips and peripheral devices including various drivers or graphic cards and suited to rapidly and uniformly cool heat unavoidably generated at the electronic device under severe work load conditions, water cooling type components should be incorporated into the electronic device from the point of an initial assembling stage. Thus, it is difficult to reconstruct an air cooling type electronic device into a water cooling type one once assembled.

Therefore, the conventional water cooling type electronic device having built-in cooling components has deteriorated performance and durability due to densely congested components. Also, since the conventional water cooling type electronic device is applicable only to the case of new manufacture, the utilization efficiency thereof is very low, resulting in poor marketability. Further, the conventional water cooling type electronic device cannot reduce its internal noise and vibration due to water cooling type components including heat-dissipating fans or circulation pumps. Electromagnetic interference (EMI) generated at the heat-dissipating fans or circulation pumps may cause malfunction inside the electronic device.

### BRIEF SUMMARY OF THE INVENTION

To solve the above problems encountered with the conventional cooling system, it is an object of the present invention to provide a water cooling type cooling system for an electronic device, which can facilitate assembling and maintenance works by simplifying internal components of the electronic device by separately installing water cooling type components outside the electronic device, and can reduce an internal temperature, noise and vibration of the electronic device.

It is another object of the present invention to provide a water cooling type cooling system for an electronic device, which can easily convert an existing air cooling type electronic device into a water cooling type one to enhance utilization efficiency and marketability and of the water cooling type cooling system and can prevent internal malfunction of the electronic device due to noise, vibration and EMI generated at heat-dissipating fans or circulation pumps.

It is still another object of the present invention to provide a water cooling type cooling system for an electronic device, which can operate both a small-sized electronic device in which a plurality of electronic components are interconnected in series or parallel and a large-sized electronic device in which a plurality of electronic components are detachably installed in a rack mount type, the electronic device operable in a water cooling type by means of coolant supply units.

In an embodiment of the present invention, there is provided a water cooling type cooling system for an electronic device including a coolant circulation unit including heat exchangers contacting heat sources inside the electronic device and internal circulation lines disposed inside the electronic device for circulating a coolant in the heat exchangers, a coolant supply unit including external circulation lines connected to the internal circulation lines of the coolant circulation unit and extending outside the electronic device so as to circulate the coolant outside the electronic device, heat-dissipating devices connected to the external circulation lines for emitting heat of the coolant into the air, circulation pumps connected to the external circulation lines for forming hydraulic pressure of the coolant, a coolant tank in which the coolant is stored, and a casing for protecting the heat-dissipating devices, the circulation pumps and the coolant tank, and a controller for controlling the circulation pumps by applying control signals to the circulation pumps.

Also, the coolant circulation unit may be configured such that the internal circulation lines are fixed to a slot assembly assembled into an internal slot of the electronic device, shut off valves are installed at the slot assembly and inlet and outlet sides of the internal circulation lines so as to be detachably connected to the external circulation lines, a waterspout tray is installed at the lower portion of the shut off values to accommodate a small amount of effluent drained during connection or disconnection of the shut off valves for protecting the circuit from the effluent, a sponge is installed inside the waterspout tray so that the effluent is absorbed or dried before it is drained out, and a connector is connected to a power source of the electronic device for supplying power to the coolant supply unit without providing a separate power source.

Also, the heat exchangers connected to the hard disk drives each may comprise a rack mount type frame in which a plurality of hard disk drives or heat sources are stacked, cooling plates each contacting the bottom of each hard disk stacked in the frame, and a connection pipe for connecting the cooling plates in series or parallel so as to allow the coolant flow therebetween.

The water cooling type cooling system according to the present invention may further include a distribution device having a plurality of ports so that a plurality of coolant circulation units are connected to the coolant supply unit in series or parallel.

The distribution device preferably has the coolant supply unit installed at the topmost layer and separate ports provided so as to seat the plurality of coolant circulation units to provide a rack mount type docking station, and intermediate circulation pumps for forcibly circulating a coolant in each rack, the coolant supply unit connected to the distribution device through coolant pipes.

### BRIEF DESCRIPTION OF THE SEVERAL VIEWS OF THE DRAWING

Like reference numerals are used to designate like parts throughout the several views of the drawing, and: The above object and advantages of the present invention will become more apparent by describing in detail preferred embodiments thereof with reference to the attached drawings in which:

FIG. 1 a conceptual diagram of a water cooling type cooling system for an electronic device according to an embodiment of the present invention applied to a desktop person computer;

FIG. 2 is a conceptual diagram of a water cooling type cooling system for an electronic device according to another embodiment of the present invention applied to a desktop person computer;

FIG. 3 is a rear view illustrating the use state of the water cooling type cooling system shown in FIG. 2;

FIG. 4 is a perspective view illustrating another example of the water cooling type cooling system shown in FIG. 2;

FIG. 5 is a plan sectional view of a coolant supply unit shown in FIG. 2;

FIG. 6 is a perspective view of a slot assembly shown in FIG. 2;

FIG. 7 is a perspective view of a coolant tank of the coolant supply unit shown in FIG. 2;

FIG. 8 is a conceptual diagram of a water cooling type cooling system for an electronic device according to another embodiment of the present invention;

FIG. 9 is a perspective view showing an example of a docking station of a water cooling type cooling system for an electronic device according to another embodiment of the present invention;

FIG. 10 is a perspective view showing another example of the system shown in FIG. 9;

FIG. 11 is a perspective view showing an example of a water cooling type cooling system for an electronic device according to still another embodiment of the present invention applied to a card type docking system;

FIG. 12 is a front view showing an example of a docking system water cooling type cooling system for an electronic device according to still another embodiment of the present invention; and

FIG. 13 is a conceptual diagram showing an example of a water cooling type cooling system for an electronic device according to still another embodiment of the present invention.

The illustrated embodiments are only examples of the present invention and, therefore, are non-limitive. It is to be understood that many changes in the particular structure, materials and features of the invention may be made without departing from the spirit and scope of the invention. Therefore, it is my intention that my patent rights not be limited by the particular embodiments illustrated and described herein, but rather are to be determined by the following claims, interpreted according to accepted doctrines of patent claim interpretation, including use of the doctrine of equivalents and reversal of parts.

### DETAILED DESCRIPTION OF THE INVENTION

A water cooling type cooling system for an electronic device according to preferred embodiments of the present invention will now be described in more detail with reference to the accompanying drawings.

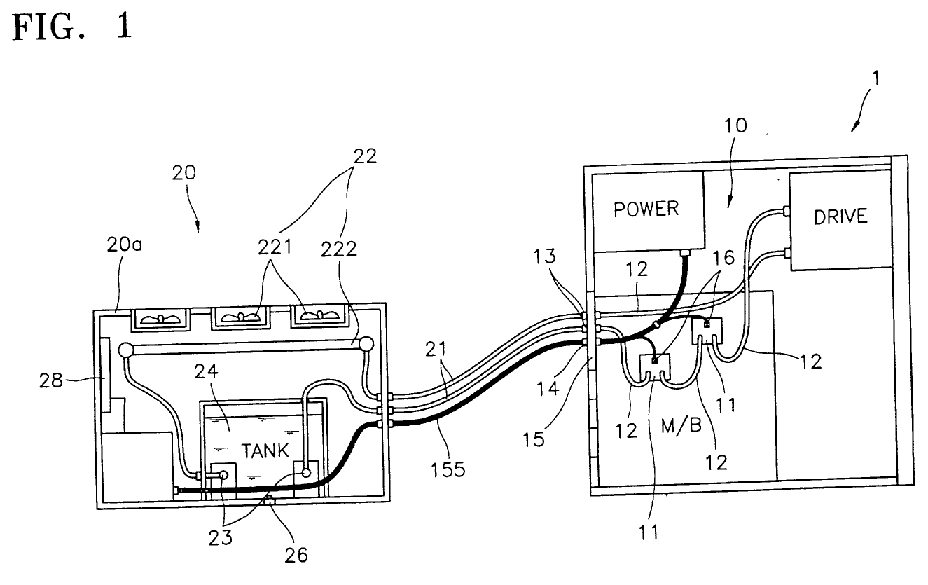

First, as shown in FIG. 1 illustrating a water cooling type cooling system for an electronic device according to an embodiment of the present invention applied to a desktop person computer, the water cooling type cooling system is largely comprised of a coolant circulation unit 10 and a coolant supply unit 20.

The coolant circulation unit 10 includes heat exchangers 11 in contact with a heat source inside a conventional electronic device 1 and internal circulation lines 12 for circulating coolants through the heat exchangers 11, and is connected to the coolant supply unit 20.

Also, the coolant circulation unit 10 includes shut off valves 13 fixed on a slot assembly 15 in which the internal circulation lines are assembled to a slot of the electronic device 1. The shut off valves 13 installed at inlets and outlets of the internal circulation lines 12 are separable valves which detachably connect the internal circulation lines 12 with external circulation lines 21.

The shut off valves 13 being in commercially widespread use are closed as soon as the external circulation lines 21 are separated from the internal circulation lines 12, thereby easily separating the external circulation lines 21 from the internal circulation lines 12 without leaking of a coolant.

The coolant supply unit 20 utilizes power for PC instead of separate power.

Also, the coolant supply unit 20 may be connected with a plurality of PC's to be connected with a plurality of coolant circulation unit 10.

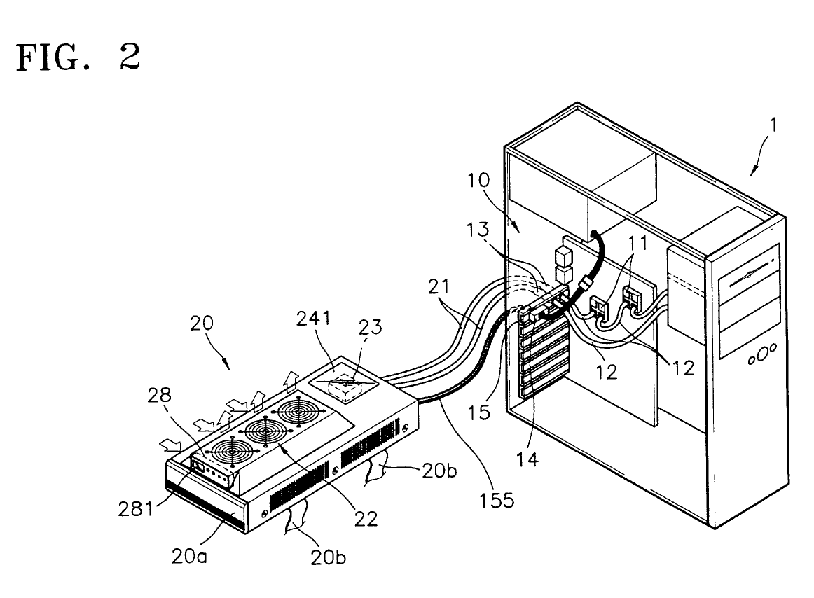

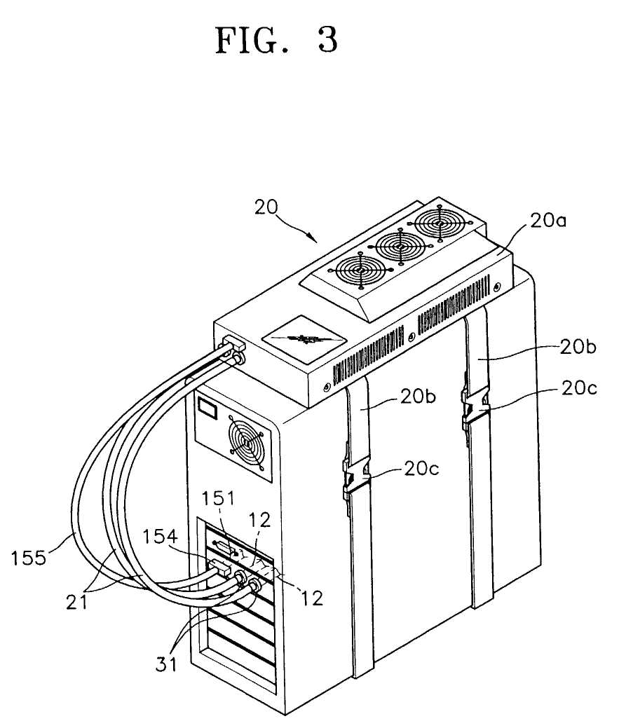

As shown in FIGS. 2 and 3 showing another embodiment of a water cooling type cooling system applied to a desktop PC, the water cooling type cooling system includes a casing 20a having a shape corresponding to that of the top plane of an electronic device 1 to allow the coolant supply unit 20 is seated thereon. The casing 20a includes cords 20b each having a buckle 20c for being fixed with a body of the electronic device 1. Instead of the cords 20b, Velcro tapes or other types of cords can be used for fixing.

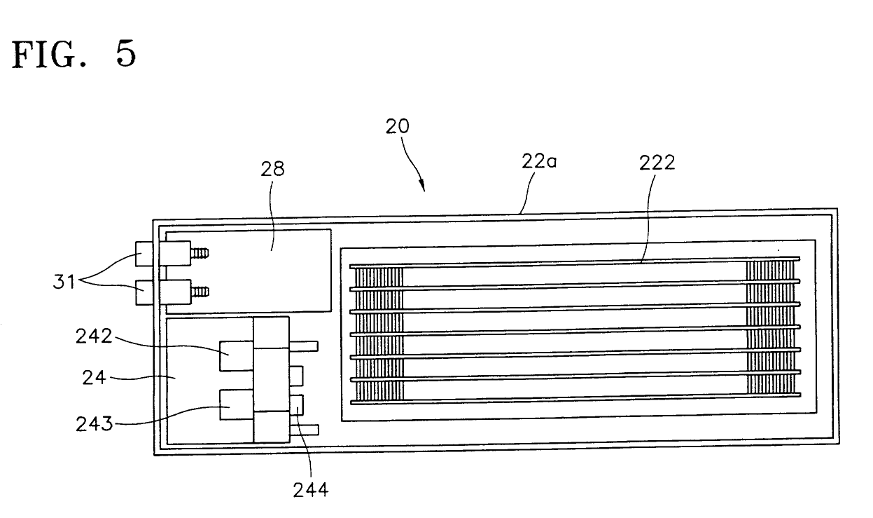

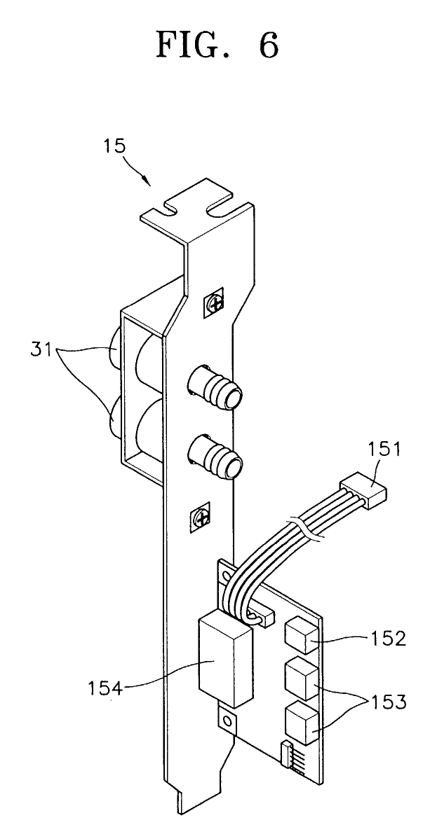

As shown in FIGS. 5 and 6, the slot assembly 15 includes shut off valves 31, a power connector 151, a temperature sensor connector 152 and internal fan control connectors 153. The shut off valves 31 connect the internal circulation lines 12 of the coolant circulation unit 10 with the external circulation lines 21 of the coolant supply unit 20. The power connector 151 connects an internal power line of the electronic device 1 with a power line of the coolant supply unit 20 for eliminating the necessity of providing a separate power source. The temperature sensor connector 152 connects a controller 28 with a temperature sensor (not shown) for measuring a temperature of a coolant in the coolant circulation unit 10 or a temperature of a CPU of the electronic device 1. The internal fan control connector 153 connects various internal fans inside the electronic device 1 with the controller 28 to allow the controller 28 to adjust speeds of the internal fans. All of the above-noted electrical wires are preferably combined with a multiple cable 155 to then be connected by a separate integrated connector 154.

In addition to the shut off valves 31, a connector 14 connected to power of the electronic device, various sensor and controllers is further installed for interconnecting power and electrical signals between the coolant supply unit 10 and various internal elements.

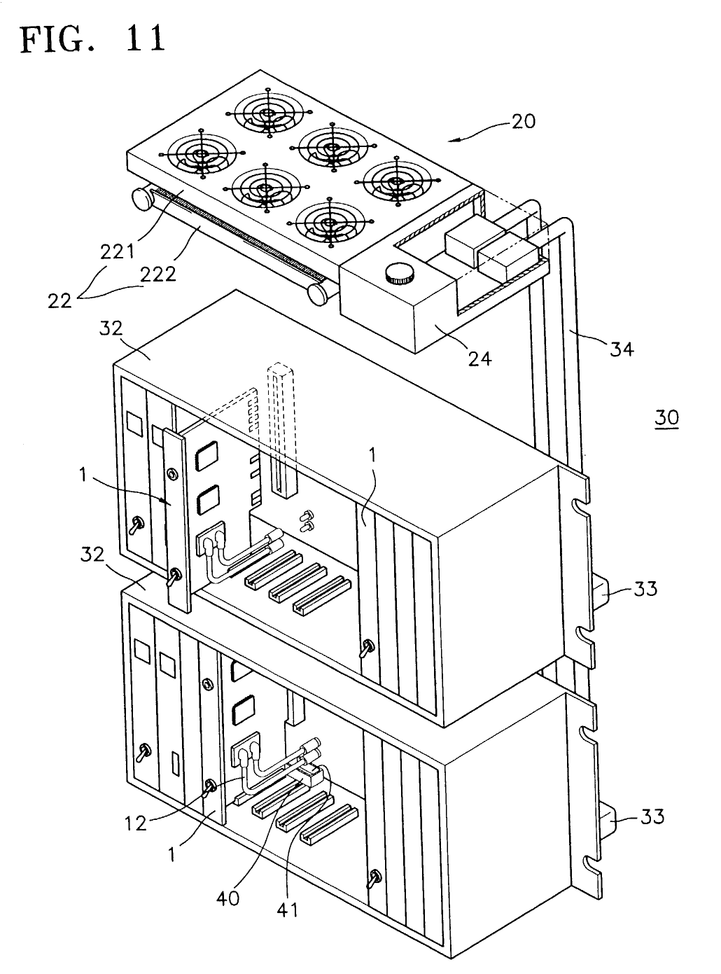

When the shut off valves 13 shown in FIG. 1 are detached from or attached to the body, since a small amount of a coolant effluent may be drained therethrough, a waterspout tray 40 is installed at the lower portion of the shut off values 13 to accommodate the effluent for protecting the circuit from the effluent, as shown in FIG. 11. Also, a sponge 41 is installed inside the waterspout tray 40 so that the effluent is absorbed or dried before it is drained out.

Thus, when a conventional air cooling type electronic device is available, the slot assembly 15 is connected to the slot inside the electronic device and the shut off valves 13 are installed. Then, the internal circulation lines 12 are assembled to the shut off valves 13 and then the heat exchangers 11 connected to the internal circulation lines 12 are connected to heat sources including CPU, video chips or hard disk drive, thereby completing an assembling work of the coolant circulation unit 10.

Also, the coolant supply unit 20 of the invention shown in FIG. 1 is connected to the coolant circulation unit 10, and includes external circulation lines 21, heat-dissipating devices 22, circulation pumps 23 and a coolant tank 24. The external circulation lines 21 are connected to the internal circulation lines 12 of the coolant circulation unit 10 and extend outside the electronic device 1 for circulation of the coolant outside the electronic device 1. The heat-dissipating devices 22 connected to the external circulation lines 21 dissipate heat in the air. The circulation pumps 23 connected to the external circulation lines 21 form hydraulic pressure of a coolant for circulation of the coolant. The coolant tank 24 stores the coolant.

The casing 20a for protecting the heat-dissipating devices 22, the circulation pumps 23 and the coolant tank 24, is spaced apart from the coolant circulation unit 10 freely irrespective of where the coolant circulation unit 10 is installed, and is connected to the external circulation lines 21.

Also, in the coolant supply unit 20 shown in FIG. 1, each of the heat-dissipating devices 22 includes a heat-dissipating fan 221 and a cooling louver fin 222 for spreading heat through the heat-dissipating fan 221. The circulation pumps 23 are installed at an inlet side and an outlet side inside the coolant tank 24. The coolant tank 24 includes a coolant stopper 26 on its bottom for refilling or replacing a coolant.

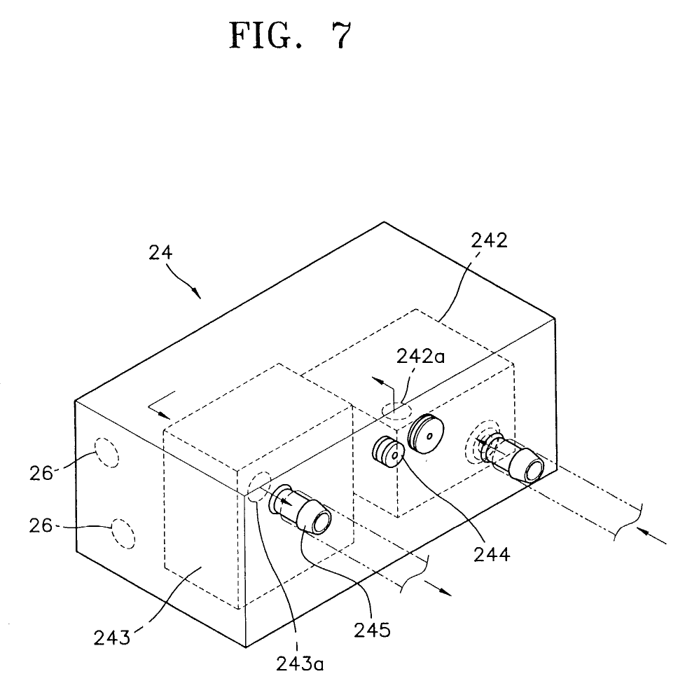

The coolant tank 24 shown in FIG. 1 can be formed in various manners. Preferably, as shown in FIG. 2, the coolant tank 24 includes a transparent case having a transparent window 241 provided on its top surface so that a user can check an amount of the coolant, an operating state of the circulation pumps and water flow. As shown in FIG. 7, an inlet pump 242 and an outlet pump 243 are installed at the inlet and outlet sides of the coolant tank 24, respectively, for stable operation. In order to allow the pumps to operate even when they lie or stand, either a discharge hole 242a of the inlet pump 242 or a discharge hole 243a of the outlet pump 243 is always made to face upward such that the discharge hole 242a of the inlet pump 242 and the discharge hole 243a of the outlet pump 243 are arranged perpendicular to each other.

Also, the coolant can be injected through two orifices disposed perpendicular to each other, thereby allowing freedom of installation. Also, an O-ring is interposed between the coolant tank body and top portion to then be ultrasonically fused, thereby achieving a secured structure and making fabrication easy.

A pressure valve 244 is installed at one side of the coolant tank 24 so as to contact a gas layer inside the coolant tank 24, thereby providing for any event of a rise in internal pressure of the pumps. Also, although not shown, an O-ring and an O-ring groove for fixing the O-ring may be formed inside each cable connecting portion 245 of the inlet and outlet sides so as to forcibly insert cables to be hermetically sealed.

As shown in FIG. 1, elements producing serious noise, vibration and EMI, such as the heat-dissipating fans 221 or circulation pumps 23, are installed in the coolant supply unit 20 to be isolated from the electronic device 1, thereby making the cooling circulation unit 10 produce no noise.

The coolant supply unit may further include the controller 28. The controller 28 receives a temperature signal from the temperature sensor 16 of the coolant circulation unit 10 to display the received temperature signal on a display 281 shown in FIG. 2. Also, the controller 28 applies a control signal programmed according to the temperature signal or set by a user to the heat-dissipating devices 22 and the hydraulic pumps 23.

As shown in FIG. 2, the controller 28 is connected to the temperature sensor (not shown) for measuring a temperature of a coolant or a temperature of the CPU and receives a temperature signal to display the same on the display 281 on the Celsius or Fahrenheit scale. According to a predetermined program, a user can selectively control operation modes of the heat-dissipating fans. That is to say, if the temperature is less than a reference temperature, the heat-dissipating fans are operated at the lowest speed. If the temperature is greater than the reference temperature, a silence mode in which the heat-dissipating fans are operated at the maximum speed or a quick mode in which the heat-dissipating fans are always operated at the highest speed is selectively set by the user.

If the temperature is greater than a first dangerous temperature, the controller 28 notifies the user of danger by means of an alarm or warning lamp. If no action is taken at a temperature greater than the first dangerous temperature for a predetermined time, or if the temperature is greater than a predetermined dangerous temperature, that is, a second dangerous temperature, the controller 28 preferably controls the power to be automatically interrupted.

Thus, the user can check abnormality in temperature of the electronic device by checking temperatures of various heat sources inside the electronic device 1 at any time, and the heat-dissipating fans 221 and the circulation pumps 23 are controlled by the controller 28, thereby maintaining the internal temperature at a constant level.

More preferably, a warning lamp or alarm is further provided so that the controller 28 drives the warning lamp or alarm when temperatures of the respective elements inside the electronic device 1 rise to a predetermined temperature or higher.

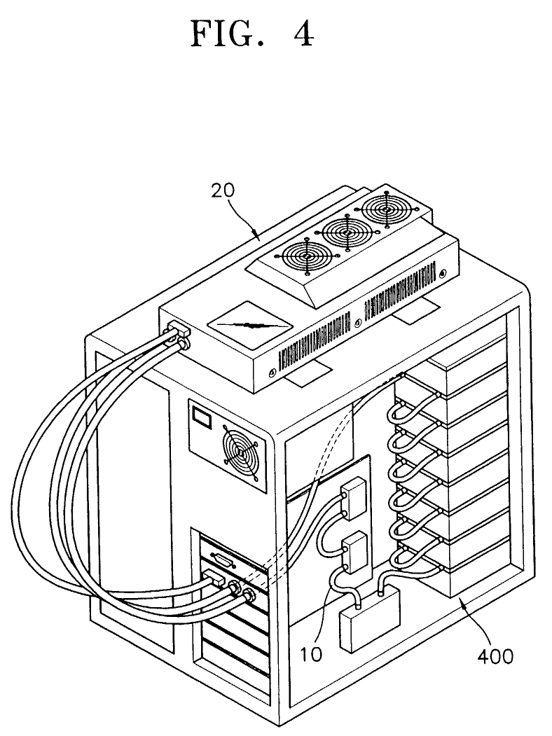

As shown in FIG. 4, the water cooling type cooling system for an electronic device according to the present invention can be applied to a desktop server computer as well as a PC. In particular, multi-layer separable cooling devices 400 directly contacting various types of storage media, such as hard disk drivers or CD-ROM drivers, and the cooling circulation unit 10 of the present invention are interconnected for cooling. In this case, a reduction in pressure and a reduction in flow rate due to an extended length of a passageway when additionally connecting a coolant tank can be prevented.

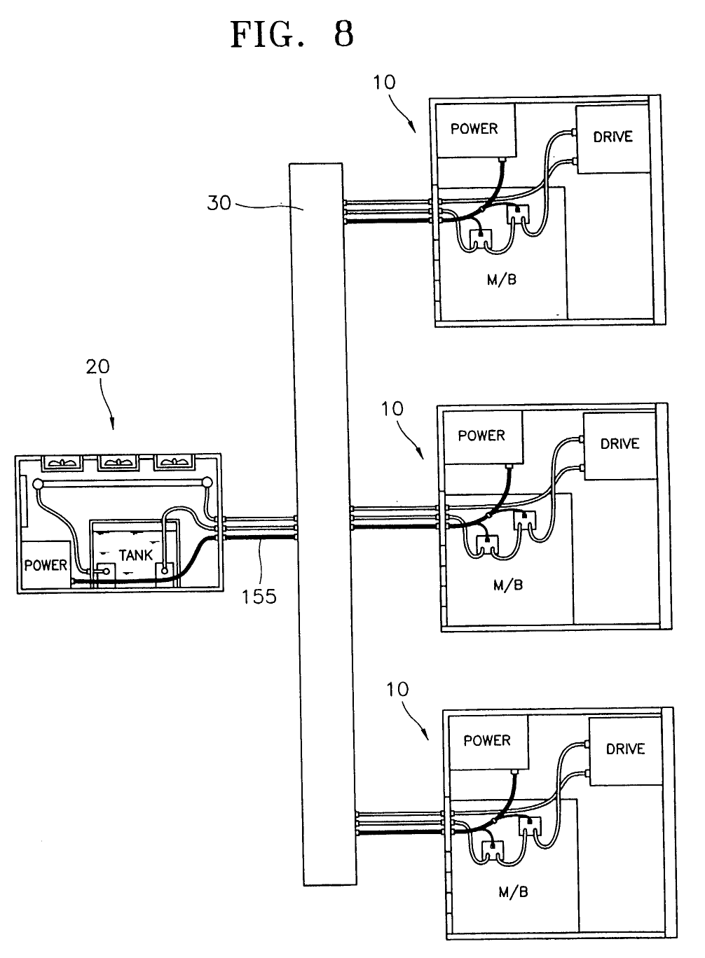

As shown in FIG. 8, the water cooling type cooling system for an electronic device according to the present invention may include a distribution device 30 having a plurality of ports so that a plurality of coolant circulation units 10 (three in the drawing) are connected to the coolant supply unit 20 in series or parallel.

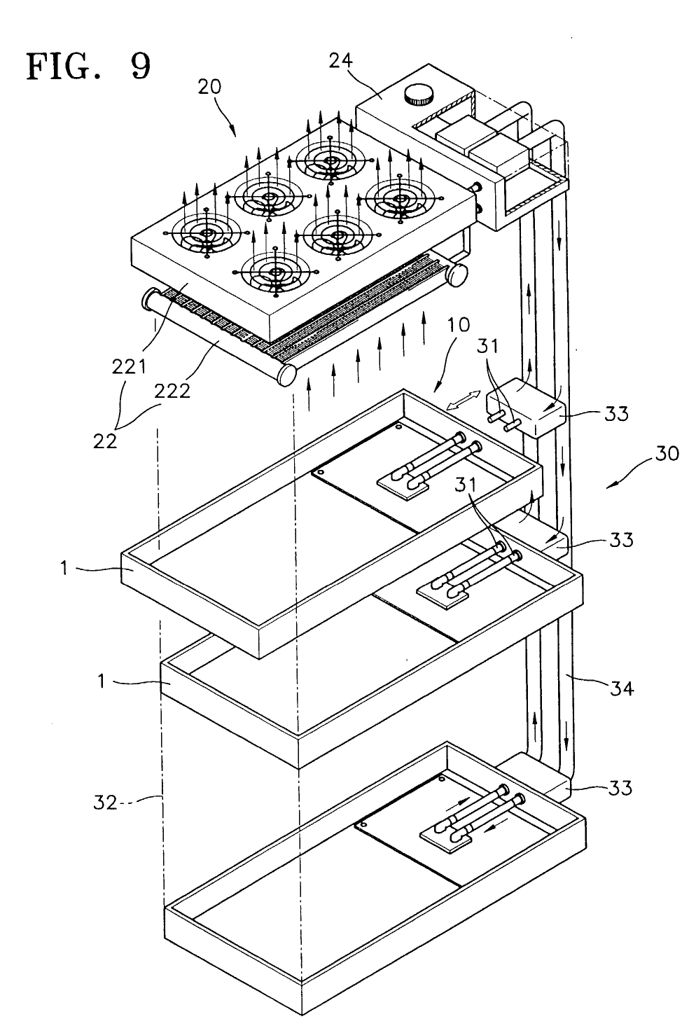

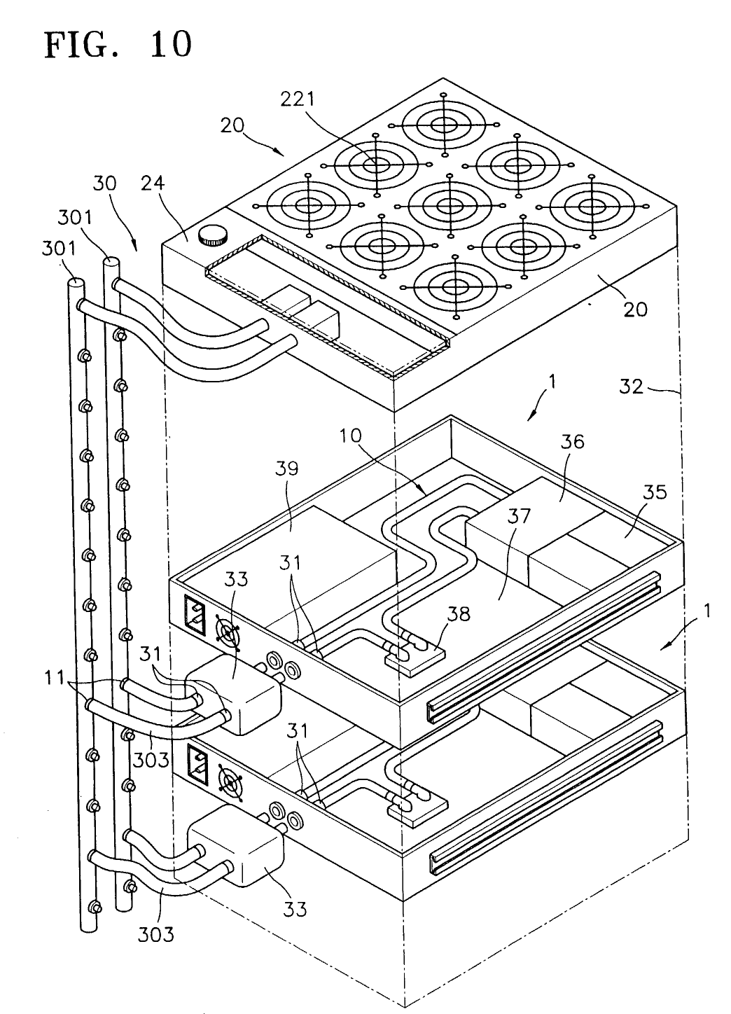

The distribution device 30 may be fabricated in various manners. As shown in FIGS. 9 and 10, the distribution device 30 can be applied to an industrial rack mount PC, for example.

In other words, the coolant supply unit 20 is installed at the topmost layer and separate ports 31 are provided so as to seat the plurality of coolant circulation units 10, thereby providing a rack mount type docking station 32.

The distribution device 30 having the rack mount type docking station 32 includes intermediate circulation pumps 33 for forcibly circulating a coolant in each rack. The coolant supply unit 20 may be connected to the distribution device 30 through coolant pipes 34.

The distribution device 30 has a water cutoff valve or a backflow preventing valve in each rack for selectively making coolant circulation in each rack on and off.

In other words, a slimmed electronic device 1 having a floppy disk driver 35, a hard disk driver 36, a mother board (M/B) 37 and a power supply 39, is connected to each rack of the rack mount type docking station 32. The electronic device 1 has the coolant circulation unit 10 provided inside. A plurality of electronic devices are assembled to be connected to a water cooling type port 31 installed in each rack, thereby achieving circulation of a coolant supplied from the coolant supply unit 20 in each coolant circulation unit 10 for each electronic device 1 installed in each rack.

Here, the coolant supplied to all electronic devices can be made to flow simultaneously by increasing the capacity of circulation pumps of the coolant supply unit 20. However, the intermediate circulation pumps 33 installed in the respective racks of the docking station 32 preferably adjust an intermediate pressure of the coolant. Thus, even if a plurality of coolant circulation units 10 are provided inside the plurality of electronic devices 1, coolant circulation in each rack can be smoothly performed without applying any tension to the circulation pumps of the coolant supply unit 20. Also, even if the pumps of the coolant supply unit 20 are out of order, it is possible to prevent all the electronic devices 1 from being interrupted.

In the docking station 32, the coolant supply unit 20 is preferably installed at the topmost layer to promote smooth dissipation of heat and induce vertical circulation in the coolant tank.

As shown in FIG. 10, the distribution device 30 for accommodating the slimmed electronic devices 1 of a horizontal stack type further includes main pipes 301 and flexible connection pipes 303. Each of the main pipes 301 is vertically disposed so as to maintain a connection between the coolant supply unit 20 and the coolant circulation unit 10 when each electronic device 1 is drawn out from the docking station 32. Each of the flexible connection pipes 303 has shut off valves 31 so as to allow connection and disconnection between the main pipe 301 and the coolant circulation unit 30, and is long enough to allow the slimmed electronic device 1 to be drawn out by a predetermined distance to then be connected to each intermediate circulation pump 33.

Here, a single pump is used as the intermediate circulation pump 33. However, a dual pump type consisting of a pair of push and pull pumps is preferably used. The intermediate circulation pump 33 may be mounted on each rack.

The slimmed electronic device 1 may be constructed in a card type in which a plurality of electronic devices 1 are vertically disposed to then be inserted into slots, as shown in FIG. 11, rather than in a horizontal stack type.

Referring back to FIG. 1, coolant circulation according to the present invention will now be described. A low-temperature coolant reaches the main board and the heat exchangers 11 installed at various heat sources, e.g., drives, along the external circulation lines 21 via the internal circulation lines 12 of the coolant circulation unit 10 by the action of the circulation pumps 23, and takes heat from the heat sources to then return to the coolant supply unit 20 along the external circulation lines 21 via the internal circulation lines 12.

Subsequently, the coolant dissipates heat while passing through the heat-dissipating devices 22 incorporated in the coolant supply unit 20 and then the low-temperature coolant returns to the coolant tank 24 to then be accommodated therein.

The controller 28 controls rotation speeds of the heat-dissipating fans 221 and the circulation pumps 23 to increase or decrease by applying control signals to the heat-dissipating fans 221 and the circulation pumps 23 according to the heat source temperatures sensed by the temperature sensor 16, or controls operation number and operation time of the heat-dissipating fans 221 and the circulation pumps 23, thereby controlling the internal temperatures of the electronic device 1.

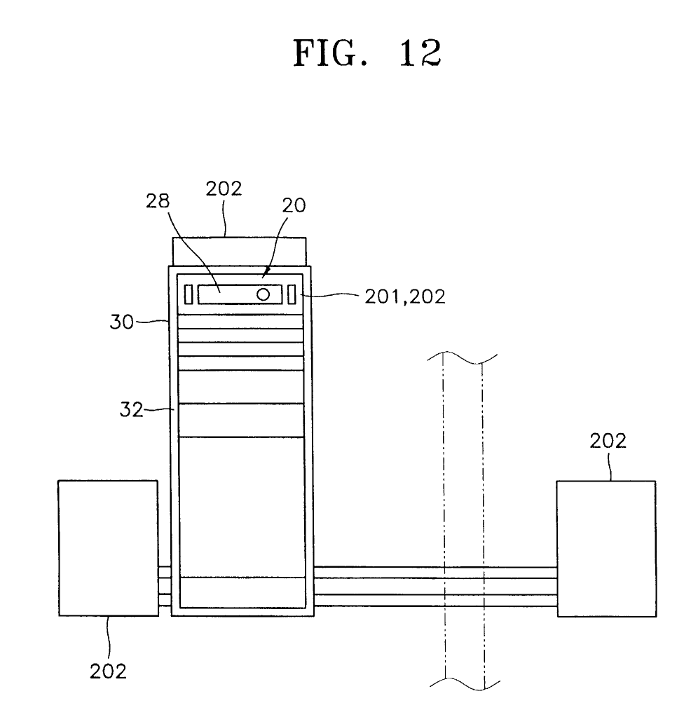

As shown in FIG. 12, the height of the slimmed electronic device 1 is controlled in standardized units on the basis of the slimmest, one unit (1U), that is, in two times (2U), four times (4U), etc.

The standard in height is applied not only to the slimmed electronic device 1 but also to a preliminary coolant supply unit 201 formed by slimming a coolant supply unit different from the coolant supply unit 20 fixed to the docking station 32 to then be inserted into the docking station 32.

In other words, the preliminary coolant supply unit 201 is inserted into a port of the docking station 32 to then be detachably connected to the coolant supply unit 20 integrally formed with the distribution device 30 by the shut off valves, thereby promoting cooling capacity of the coolant supply unit 20.

The preliminary coolant supply unit 201 is formed in an air cooling type. However, the preliminary coolant supply unit 201 may be formed in a refrigerator type to enhance cooling capacity.

The refrigerator type preliminary coolant supply unit 202 includes a compressor and a dilator to be operated according to cooling cycle.

Unlike an air cooling type supply unit dissipating heat by means of heat-dissipating fans, the refrigerator type preliminary coolant supply unit 202 utilizes the operating principle of existing refrigerators using latent heat absorbed when a coolant compressed depending on a pumping rate of a compressor expands in the dilator, thereby greatly increasing cooling capacity.

In order to reduce cooling load, the controller 28 preferably controls two or more air cooling type preliminary coolant supply units 201 or refrigerator type preliminary coolant supply units 202 to be alternately operated.

In order to prevent dew condensation which is fatal to circuitry, the controller 28 may include a temperature sensor (not shown) and a humidity sensor (not shown) for sensing an external temperature and humidity, to calculate a temperature immediately before dew is produced based on season and humidity, thereby applying control signals to the coolant supply unit 20 or the preliminary coolant supply units 201 and 202 so as to maintain the lowest temperature within a range in which dew is not produced.

As shown in FIG. 12, the refrigerator type preliminary coolant supply unit 202 may be installed at an upper or lower portion inside the docking station 32. Otherwise, the refrigerator type preliminary coolant supply unit 202 may be seated on the top or side surface of the docking station 32. Also, the refrigerator type preliminary coolant supply unit 202 may be externally provided to then be connected to the docking station 32.

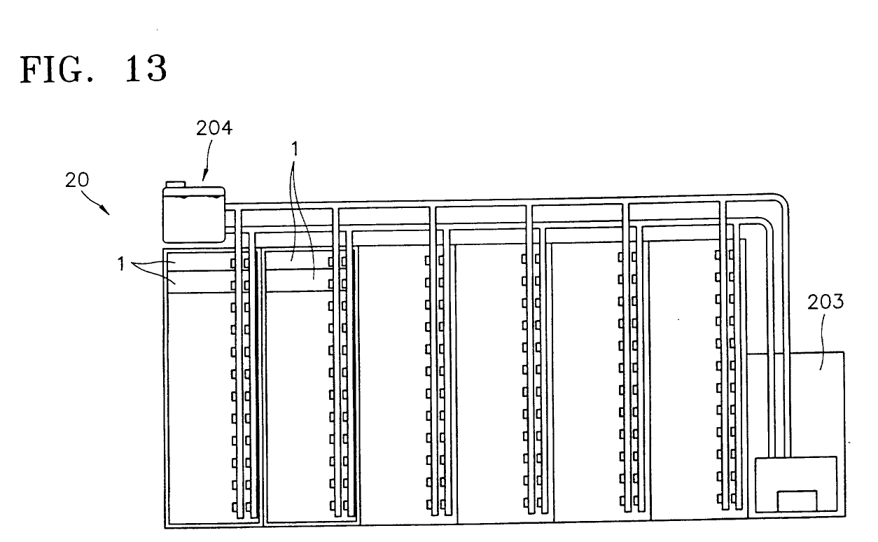

The refrigerator type preliminary coolant supply unit 202 is not necessarily mounted as a preliminary coolant supply unit. As shown in FIG. 13, the refrigerator type preliminary coolant supply unit 202 may be installed instead of the coolant supply unit 20 (???). Otherwise, the refrigerator type preliminary coolant supply unit 202 may be configured such that a refrigerator structure is made into a module to install a main coolant tank 204 and/or a refrigerator chiller 203 for supplying cold water to the electronic device 1, thereby providing a stacked structure to each slimmed electronic device 1.

Therefore, the water cooling type cooling system according to the present invention is provided with only a one-phase type cooling system for cooling a heat-generating element while circulating in a liquid state but also a two-phase type cooling system capable of promoting the cooling capacity of the one-phase type cooling system, thereby achieving a combined cooling system.

Although specific embodiments have been illustrated and described, it will be obvious to those skilled in the art that various modifications may be made without departing from what is intended to be limited solely by the appended claims. For example, it has been described in the above-described embodiments of the present invention that the heat-dissipating devices, the coolant tank and the circulation pumps are incorporated into the coolant supply unit. However, some elements including the coolant tank may be incorporated in the coolant circulation unit. Otherwise, various types of water cooling type cooling systems for an electronic device separately provided with a coolant circulation unit and an external part may be used.

Therefore, it is to be understood that the invention is not to be limited to the disclosed embodiments but, on the contrary, is intended to cover various modifications and equivalent arrangements included within the spirit and scope of the appended claims.

As described above, according to the water cooling type cooling system for an electronic device of the present invention, water cooling type elements provided inside the electronic device are externally installed separately from the electronic device, thereby simplifying internal parts of the electronic device to facilitate assembling and maintenance works, reducing an internal temperature of the electronic device and reducing noise and vibration inside the electronic device. Also, a conventional air cooling type electronic device can be easily converted into a water cooling type one, thereby enhancing utilization efficiency and marketability and prevent internal malfunction of the electronic device due to noise, vibration and EMI generated at heat-dissipating fans or circulation pumps. Further, since a plurality of small-sized electronic components are interconnected in series or parallel, a detachable, rack mount type, large-sized electronic device can be operated in a water cooling type.

What is claimed is:

1. A water cooling type cooling system for an electronic device comprising:
a coolant circulation unit including heat exchangers contacting heat sources inside the electronic device and internal circulation lines disposed inside the electronic device for circulating a coolant in the heat exchangers;
a coolant supply unit including external circulation lines connected to the internal circulation lines of the coolant circulation unit and extending outside the electronic device so as to circulate the coolant outside the electronic device, heat-dissipating devices connected to the external circulation lines for emitting heat of the coolant into the air, circulation pumps connected to the external circulation lines for forming hydraulic pressure of the coolant, a coolant tank in which the coolant is stored, and a casing for protecting the heat-dissipating devices, the circulation pumps and the coolant tank; and
a controller for controlling the circulation pumps by applying control signals to the circulation pumps.

2. The water cooling type cooling system according to claim 1, wherein the coolant circulation unit is configured such that the internal circulation lines are fixed to a slot assembly assembled into an internal slot of the electronic device, shut off valves are installed at the slot assembly and inlet and outlet sides of the internal circulation lines so as to be detachably connected to the external circulation lines, a waterspout tray is installed at the lower portion of the shut off values to accommodate a small amount of effluent drained during connection or disconnection of the shut off valves for protecting the circuit from the effluent, a sponge is installed inside the waterspout tray so that the effluent is absorbed or dried before it is drained out, and a connector is connected to a power source of the electronic device for supplying power to the coolant supply unit without providing a separate power source.

3. The water cooling type cooling system according to claim 1, wherein the coolant circulation unit has the heat exchangers connected to heat sources including a CPU, video chips and hard disk drives, the heat exchangers interconnected in series or parallel.

4. The water cooling type cooling system according to claim 3, wherein the heat exchangers connected to the hard disk drives each comprises:
a rack mount type frame in which a plurality of hard disk drives or heat sources are stacked;
cooling plates each contacting the bottom of each hard disk stacked in the frame; and
a connection pipe for connecting the cooling plates in series or parallel so as to allow the coolant flow therebetween.

5. The water cooling type cooling system according to claim 1, wherein the coolant supply unit has each of the heat-dissipating devices including a heat-dissipating fan and a cooling louver fin for spreading heat through the heat-dissipating fan, the coolant tank includes a transparent case having a transparent window provided on its top surface so that a user can check an amount of the coolant, an operating state of the circulation pumps and water flow, an inlet pump and an outlet pump installed at the inlet and outlet sides thereof, respectively, for stable operation, in order to allow the pumps to operate even when they lie or stand, either a discharge hole of the inlet pump or a discharge hole of the outlet pump is always made to face upward such that the discharge hole of the inlet pump and the discharge hole of the outlet pump are arranged perpendicular to each other, the coolant can be injected through two orifices disposed perpendicular to each other, thereby allowing freedom of installation, and an O-ring is interposed between the coolant tank body and top portion to then be ultrasonically fused, thereby achieving a secured structure and making fabrication easy.

6. The water cooling type cooling system according to claim 1, wherein the controller is connected to a temperature sensor for measuring a temperature of a coolant or a temperature of the CPU and receives a temperature signal to display the same on a display on the Celsius or Fahrenheit scale; according to a predetermined program, the controller controls the heat-dissipating fans to be operated at the lowest speed if the temperature is less than a reference temperature, and a silence mode in which the heat-dissipating fans are operated at the maximum speed or a quick mode in which the heat-dissipating fans are always operated at the highest speed is selectively set by the user if the temperature is greater than the reference temperature; and wherein the controller notifies the user of danger by means of an alarm or warning lamp if the temperature is greater than a first dangerous temperature, and the controller controls the power to be automatically interrupted if no action is taken at a temperature greater than the first dangerous temperature for a predetermined time or if the temperature is greater than a predetermined dangerous temperature.

7. The water cooling type cooling system according to claim 1, further comprising a distribution device having a plurality of ports so that a plurality of coolant circulation units are connected to the coolant supply unit in series or parallel.

8. The water cooling type cooling system according to claim 7, wherein the distribution device has the coolant supply unit installed at the topmost layer and separate ports provided so as to seat the plurality of coolant circulation units to provide a rack mount type docking station, and intermediate circulation pumps for forcibly circulating a coolant in each rack, the coolant supply unit connected to the distribution device through coolant pipes.

9. The water cooling type cooling system according to claim 8, further comprising a preliminary coolant supply unit inserted into a port of the docking station to then be detachably connected to the coolant supply unit integrally formed with the distribution device by the shut off valves.

10. The water cooling type cooling system according to claim 8, wherein the distribution device comprises:
main pipes each vertically disposed so as to maintain a connection between the coolant supply unit and the coolant circulation unit when each electronic device is drawn out from the docking station; and
flexible connection pipes each having shut off valves so as to allow connection and disconnection between the main pipe and the coolant circulation unit and long enough to allow the slimmed electronic device to be drawn out by a predetermined distance to then be connected to each of the intermediate circulation pumps.

11. The water cooling type cooling system according to claim 10, wherein the intermediate circulation pump includes a single pump installed on the flexible connection pipes or a pair of push and pull pumps fixed to the coolant circulation unit of the slimmed electronic device.

12. The water cooling type cooling system according to claim 9, wherein, the preliminary coolant supply unit includes a refrigerator type preliminary coolant supply unit having a compressor and a dilator to be operated according to cooling cycle, two or more air cooling type preliminary coolant supply units are controlled to be alternately operated, and the controller includes a temperature sensor and a humidity sensor for sensing an external temperature and humidity, to calculate a temperature immediately before dew is produced based on season and humidity, thereby applying control signals to the coolant supply unit or the preliminary coolant supply units so as to maintain the lowest temperature within a range in which dew is not produced.
